(19) United States
(12) Patent Application Publication
(10) Pub. No.: US 2026/0042494 A1
(43) Pub. Date: Feb. 12, 2026

(54) VEHICLE AERODYNAMIC COMPONENTS INCLUDING PIEZOELECTRIC ELEMENTS

(71) Applicant: GM Global Technology Operations LLC, Detroit, MI (US)

(72) Inventors: Spencer TAFT, Victoria (CA); Philip C. Lundberg, Sylvan Lake, MI (US); Edward A. Vietor, Farmington Hills, MI (US)

(21) Appl. No.: 18/795,518

(22) Filed: Aug. 6, 2024

(51) Int. Cl. B62D 35/00; G01B 7/16; H10N 30/30; H10N 30/857

(52) U.S. Cl. CPC B62D 35/007; B62D 35/005; G01B 7/16; H10N 30/302; H10N 30/857

(57) ABSTRACT

A vehicle control system for a vehicle aerodynamic element includes an aerodynamic element coupled with a body of a vehicle, the aerodynamic element configured to deform in response to wind forces exerted on a surface of the aerodynamic element, at least one piezoelectric element coupled with the aerodynamic element, the piezoelectric element configured to change voltage in response to deformation of the aerodynamic element, and a vehicle control module configured to obtain a steady state voltage value of the piezoelectric element corresponding to a position of the aerodynamic element while a speed of the vehicle is zero, receive a current voltage value of the piezoelectric element, and determine a deformation amount of the aerodynamic element based on a voltage difference between the steady state voltage value and the current voltage value.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure generally relates to vehicle control systems for vehicle aerodynamic components, including vehicle aerodynamic components having piezoelectric elements to determine deformation of the vehicle aerodynamic components.

Some vehicles include aerodynamic components, such as rear wings, which generate downforce for the vehicle. Surfaces of the aerodynamic components deform under forces such as wind loads, and deformation of the surfaces may reduce the amount of downforce provided by the aerodynamic components.

### SUMMARY

A vehicle control system for a vehicle aerodynamic element includes an aerodynamic element coupled with a body of a vehicle, the aerodynamic element configured to deform in response to wind forces exerted on a surface of the aerodynamic element, at least one piezoelectric element coupled with the aerodynamic element, the piezoelectric element configured to change voltage in response to deformation of the aerodynamic element, and a vehicle control module configured to obtain a steady state voltage value of the piezoelectric element corresponding to a position of the aerodynamic element while a speed of the vehicle is zero, receive a current voltage value of the piezoelectric element, and determine a deformation amount of the aerodynamic element based on a voltage difference between the steady state voltage value and the current voltage value.

In some examples, the at least one piezoelectric element includes multiple piezoelectric elements, and each of the multiple piezoelectric elements is coupled with a different portion of the aerodynamic element.

In some examples, a first one of the multiple piezoelectric elements is coupled with the aerodynamic element in a first orientation, a second one of the multiple piezoelectric elements is coupled with the aerodynamic element in a second orientation, and the first orientation is perpendicular to the second orientation.

In some examples, the at least one piezoelectric element is attached to a top surface of the aerodynamic element.

In some examples, the at least one piezoelectric element is housed within the aerodynamic element, and is attached to a bottom side of a top surface of the aerodynamic element.

In some examples, the aerodynamic element is a rear wing of the vehicle. In some examples, the at least one piezoelectric element includes a piezoelectric polymer.

In some examples, the piezoelectric polymer includes a single top electrode layer and a matrix layer, the matrix layer including a matrix of bottom electrodes, and the piezoelectric polymer is positioned between the single top electrode layer and the matrix layer.

In some examples, the vehicle control module is configured to selectively apply voltage to the piezoelectric element to modify deformation of the aerodynamic element.

In some examples, the vehicle control module is configured to compare the voltage difference to a specified deformation threshold value, and in response to the voltage difference being greater than or equal to the specified deformation threshold value, apply voltage to the piezoelectric element to reduce deformation of the aerodynamic element to compensate for wind forces on the aerodynamic element.

In some examples, the vehicle control module is configured to determine, based on one or more sensed vehicle parameters, whether an additional downforce condition is satisfied, and in response to the additional downforce condition being satisfied, apply voltage to the piezoelectric element to reduce deformation of the aerodynamic element.

In some examples, the aerodynamic element is a front aerodynamic element located at a front portion of the vehicle, the vehicle control system further includes a rear aerodynamic element located at a rear of the vehicle, the at least one piezoelectric element includes a front piezoelectric element coupled with the front aerodynamic element and a rear piezoelectric element coupled with the rear aerodynamic element, the vehicle control module is configured to selectively apply voltage to the front piezoelectric element to modify deformation of the front aerodynamic element, and the vehicle control module is configured to selectively apply voltage to the rear piezoelectric element to modify deformation of the rear aerodynamic element.

In some examples, the vehicle control module is configured to selectively apply a voltage opposite which is opposite to the voltage difference, to the piezoelectric element, to increase deformation of the aerodynamic element.

A method of sensing deformation of a vehicle aerodynamic element, the method comprising obtaining a steady state voltage value of at least one piezoelectric element coupled with an aerodynamic element, wherein the aerodynamic element is coupled with a body of a vehicle and configured to deform in response to wind forces exerted on a surface of the aerodynamic element, the piezoelectric element configured to change voltage in response to deformation of the aerodynamic element; and the steady state voltage value corresponds to a position of the aerodynamic element while a speed of the vehicle is zero, receiving a current voltage value of the piezoelectric element, and determining a deformation amount of the aerodynamic element based on a voltage difference between the steady state voltage value and the current voltage value.

In some examples, the method includes selectively applying voltage to the piezoelectric element to modify deformation of the aerodynamic element.

In some examples, the method incudes comparing the voltage difference to a specified deformation threshold value, and in response to the voltage difference being greater than or equal to the specified deformation threshold value, applying voltage to the piezoelectric element to reduce deformation of the aerodynamic element to compensate for wind forces on the aerodynamic element.

In some examples, the method includes determining, based on one or more sensed vehicle parameters, whether an additional downforce condition is satisfied, and in response to the additional downforce condition being satisfied, applying voltage to the piezoelectric element to reduce deformation of the aerodynamic element.

In some examples, the aerodynamic element is a front aerodynamic element located at a front portion of the vehicle, the vehicle includes a rear aerodynamic element located at a rear of the vehicle, and the at least one piezoelectric element includes a front piezoelectric element coupled with the front aerodynamic element and a rear piezoelectric element coupled with the rear aerodynamic element, and the method further includes selectively applying voltage to the front piezoelectric element to modify deformation of the front aerodynamic element, and selectively applying voltage to the rear piezoelectric element to modify deformation of the rear aerodynamic element.

In some examples, the method includes selectively applying a voltage opposite which is opposite to the voltage difference, to the piezoelectric element, to increase deformation of the aerodynamic element.

In some examples, the method includes adjusting at least one aero surface of the vehicle according to the voltage difference, to increase at least one of a movement efficiency parameter of the vehicle and a downforce parameter of the vehicle.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example embodiment of a vehicle including a control system for a vehicle aerodynamic component including a piezoelectric element;

FIG. 2 is a line drawing illustrating example piezoelectric elements located on different portions of a vehicle aerodynamic component;

FIGS. 3 and 4 are side views of a piezoelectric element located on a rear wing experiencing wind forces;

FIG. 5 is an exploded view illustrating an example piezoelectric element including a piezoelectric polymer;

FIG. 6 is a flowchart depicting an example process for applying voltage to a piezoelectric element of a vehicle aerodynamic component; and

FIG. 7 is a flowchart depicting an example process for selectively applying voltage to front or rear piezoelectric elements to control vehicle downforce.

In the drawings, reference numbers may be reused to identify similar and/or identical elements.

### DETAILED DESCRIPTION

In some example embodiments described herein, a piezoelectric element (e.g., a piezoelectric material, plate, polymer, etc.) is applied to a vehicle aerodynamic component which deflects under load, such as a wind load or air resistance as the vehicle is moving. This deflection of the vehicle aerodynamic component is measured via a change of voltage in the piezoelectric element. For example, a problem of measuring deflection of a vehicle aerodynamic element via wind force may be addressed by applying various piezoelectric structures to the aerodynamic element, in order to measure the deflection via a change in voltage of the piezoelectric structures.

In some examples, the piezoelectric material to is applied to aerodynamic elements of a vehicle by using the piezoelectric material at a boundary of a deflecting surface of the aerodynamic element, to measure deflection of the aerodynamic element (e.g., how much the surface moves under a wind load). Increased resolution of deflection measurement and detection may be facilitated by separating the electrodes of the piezoelectric material into smaller electrically isolated segments, or isolating piezoelectric segments. This produces information about the deflection of the aerodynamic surface per segment.

The piezoelectric element may be charged, such as by applying a voltage to the piezoelectric element from a voltage source, which can manipulate the shape of the vehicle aerodynamic component. For example, force may be applied to an aerodynamic element of the vehicle using the same or different piezoelectric assembly that is used to measure surface deflection. This facilitates manipulation of the vehicle aerodynamic element by bending the aerodynamic element at specific portions using a voltage applied across the piezoelectric element.

Some example embodiments facilitate closed circuit monitoring of the deflection of an aerodynamic element. If the vehicle aerodynamic element is lost in a collision, for example, the resulting open circuit may indicate that the vehicle aerodynamic element has been lost. Using multiple piezoelectric elements facilitates obtaining further details on which portions of the aerodynamic element have been damaged.

One of the complications in utilizing active aerodynamic surfaces is determining the actual forces created. The forces are a function of numerous continually changing factors, such as wind speed, wind direction, air density, etc. Measuring the deflection of the surfaces allows vehicle control systems to better estimate the forces, which enables more precise control of the surfaces. This provides benefits ranging from better fuel economy and reduced emissions to higher top speed.

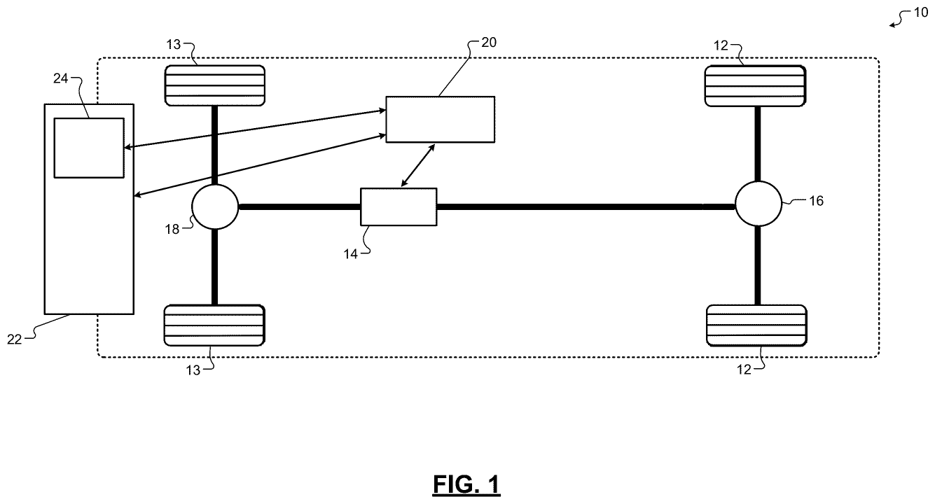

Referring now to FIG. 1, a vehicle 10 includes front wheels 12 and rear wheels 13. In FIG. 1, a drive unit 14 selectively outputs torque to the front wheels 12 and/or the rear wheels 13 via drive lines 16, 18, respectively. The vehicle 10 may include different types of drive units. For example, the vehicle may be an electric vehicle such as a battery electric vehicle (BEV), a hybrid vehicle, or a fuel cell vehicle, a vehicle including an internal combustion engine (ICE), or other type of vehicle.

Some examples of the drive unit 14 may include any suitable electric motor, a power inverter, and a motor controller configured to control power switches within the power inverter to adjust the motor speed and torque during propulsion and/or regeneration. A battery system provides power to or receives power from the electric motor of the drive unit 14 via the power inverter during propulsion or regeneration.

While the vehicle 10 includes one drive unit 14 in FIG. 1, the vehicle 10 may have other configurations. For example, two separate drive units may drive the front wheels 12 and the rear wheels 13, one or more individual drive units may drive individual wheels, etc. As can be appreciated, other vehicle configurations and/or drive units can be used.

The vehicle control module 20 may be configured to control the operation of one or more vehicle components, such as the drive unit 14 (e.g., by commanding torque settings of an electric motor of the drive unit 14). The vehicle control module 20 may receive inputs for controlling components of the vehicle, such as signals received from a steering wheel, an acceleration paddle, etc. The vehicle control module 20 may monitor telematics of the vehicle for safety purposes, such as vehicle speed, vehicle location, vehicle braking and acceleration, etc.

The vehicle control module 20 may receive signals from any suitable components for monitoring one or more aspects of the vehicle, including one or more vehicle sensors (such as cameras, microphones, pressure sensors, wheel position sensors, location sensors such as global positioning system (GPS) antennas, etc.). Some sensors may be configured to monitor current motion of the vehicle, acceleration of the vehicle, steering torque, etc.

As shown in FIG. 1, the vehicle 10 includes an aerodynamic component 22, which may include any suitable aerodynamic element of the vehicle, such as a rear wing, a front wing, side surfaces, etc., which may be used to provide aerodynamic forces on the vehicle 10. The aerodynamic component 22 may be fixed, may be controllable to different positions to adjust downforce in a controlled manner (such as via one or more actuators or motors), etc.

The aerodynamic component 22 may be located at any suitable position on the vehicle 10. Although FIG. 1 illustrates one aerodynamic component located on a rear of the vehicle, other example embodiments may include more aerodynamic components, aerodynamic components having different shapes, aerodynamic components at different locations, etc.

A piezoelectric element 24 is coupled with the aerodynamic element. The piezoelectric element 24 may include any suitable piezoelectric material, piezoelectric plate, piezoelectric polymer, etc. As described further below, the piezoelectric element 24 may include electrodes, such as a top electrode, a matrix of bottom electrodes including inner and outer electrodes, etc.

Although FIG. 1 illustrates one piezoelectric element on the aerodynamic component 22, other example embodiments may include more piezoelectric elements, piezoelectric elements at different locations, piezoelectric elements on different aerodynamic components, etc. For example, segments of piezoelectric elements may be placed at different locations on a same aerodynamic component, or multiple piezoelectric elements on a same aerodynamic component, to determine how deformation is occurring at multiple locations of a same aerodynamic component.

The vehicle control module 20 may communicate with another device via a wireless communication interface, which may include one or more wireless antennas for transmitting and/or receiving wireless communication signals. For example, the wireless communication interface may communicate via any suitable wireless communication protocols, including but not limited to vehicle-to-everything (V2X) communication, Wi-Fi communication, wireless area network (WAN) communication, cellular communication, personal area network (PAN) communication, short-range wireless communication (e.g., Bluetooth), etc. The wireless communication interface may communicate with a remote computing device over one or more wireless and/or wired networks. Regarding the vehicle-to-vehicle (V2X) communication, the vehicle 10 may include one or more V2X transceivers (e.g., V2X signal transmission and/or reception antennas).

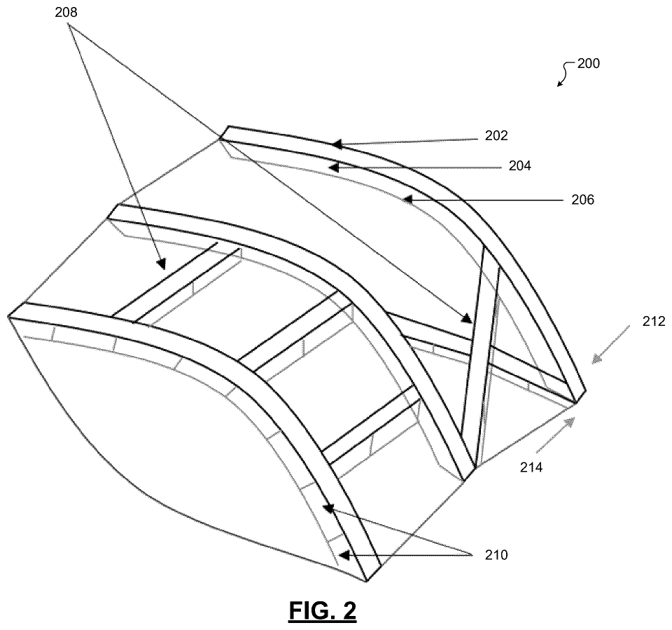

FIG. 2 is a line drawing illustrating example piezoelectric elements located on different portions of a vehicle aerodynamic element 200. In the example of FIG. 2, an outer electrode 202 of a piezoelectric element is placed along the inside of the vehicle aerodynamic element 200.

The piezoelectric element includes an inner electrode 206, and a piezoelectric plate 204 located between the outer electrode 202 and the inner electrode 206. The piezoelectric element may measure deformation of the surface of the vehicle aerodynamic element 200, based on voltage changes between the outer electrode 202 and the inner electrode 206.

Optionally, one or more piezoelectric elements 208 may be used on a crossbar of the vehicle aerodynamic element 200, as a crosshatch piezoelectric plate design, etc., to measure deflection of the vehicle aerodynamic element 200 in different directions, such as a perpendicular direction compared to the piezoelectric plate 204. Segment piezoelectric plates 210, or segment electrodes of piezoelectric elements, may be used to measure deflection in specific areas of the vehicle aerodynamic element 200.

In the example of FIG. 2, wind forces 212 cause deflection of the vehicle aerodynamic element 200, such as air resistance while the vehicle is moving. In some examples, voltage may be selectively applied to a piezoelectric element to supply a piezoelectric force 214 to counter the wind forces 212. For example, if the wind forces 212 cause deflection of part of the aerodynamic element 200, voltage may be applied to the piezoelectric element to push the surface of the aerodynamic element 200 out and reduce deflection, to counter the wind forces 212.

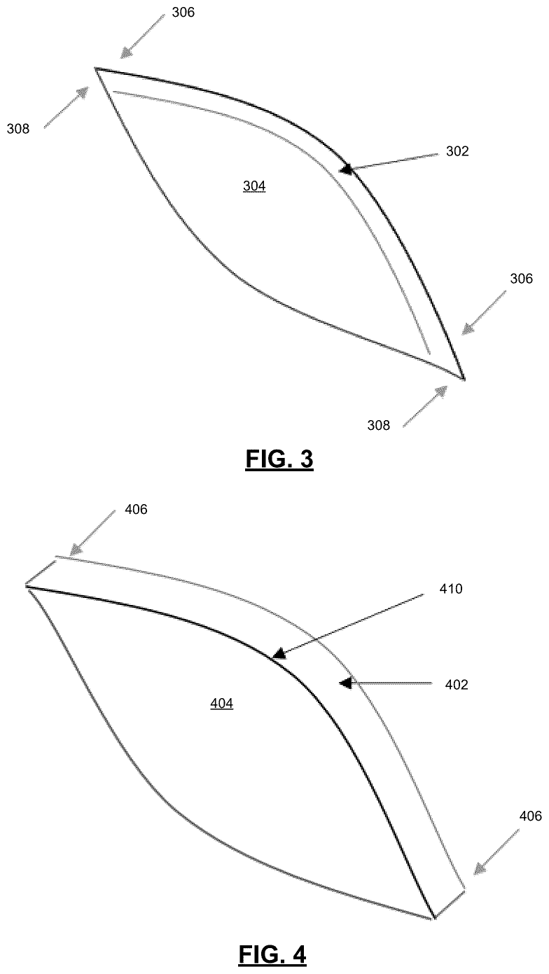

FIGS. 3 and 4 are side views of a piezoelectric element located on a rear wing experiencing wind forces. As shown in FIG. 3, a piezoelectric plate 302 is housed in a wing 304 of the vehicle (e.g., a rear wing or front wing), along the underside of a top surface of the wing 304.

Deflection of the wing 304 may be controlled by the piezoelectric plate 302. For example, if wind forces 306 deform the top surface of the wing 304, voltage may be applied to the piezoelectric plate 302 to generate a piezoelectric force 308. The piezoelectric force pushes against the top surface of the wing 304, to reduce deformation of wing 304. This may counter the wind force 306, so the wing 304 continues to provide desired downforce even in the presence of the wind forces 306.

The example of the wing 404 in FIG. 4 is similar to the wing 304 of FIG. 3, but the piezoelectric plate 402 is located on an outside of the top surface 410 of the wing 404. For example, the piezoelectric plate 402 may be bent along with the top surface 410 of the wing 404, subjecting the piezoelectric plate 402 to tension. The arrangement of FIG. 4 may generate a positive current as the top surface 410 of the wing 404 is deformed due to the wind forces 406.

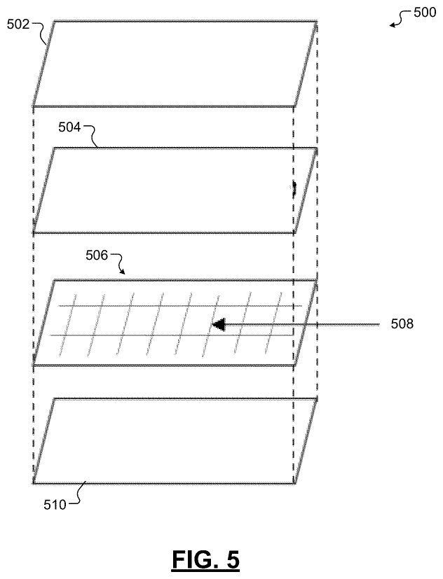

FIG. 5 is an exploded view illustrating an example piezoelectric element assembly 500 including a piezoelectric polymer 504. The piezoelectric element assembly 500 includes a top electrode 502 as a top layer, which may include a single, elastic electrode.

The bottom layer of the piezoelectric element assembly 500 is a wing surface 510. A matrix layer 506 is located on the wing surface 510. The matrix layer 506 may include a matrix of bottom electrodes, which includes multiple inner electrodes 508. The inner electrodes 508 may provide an array of contact points for measuring change in current per section area.

The piezoelectric polymer 504 is located between the top electrode 502, and the matrix layer 506 of bottom electrodes. The piezoelectric polymer 504 may include any suitable piezoelectric polymer material. In some examples, the top electrode 502 and the matrix layer 506 of bottom electrodes may measure a distribution of wind force across an aero component. This may be applied to any part of a vehicle subject to wind (e.g., a wing, a hood, etc.) to measure wind force, for analysis, for calibrating simulation software, etc.

In some examples, the determined deflection of the aerodynamic components may be used to adjust a control setting of a vehicle component, such as changing a position (e.g., angle or height) of a vehicle aerodynamic component, changing a traction control setting, changing a ride height setting, limiting a top vehicle speed, changing braking settings, etc.

In some example embodiments, a strip or multiple strips of piezoelectric polymer or piezoelectric plates may be attached to an aerodynamic element or aerodynamic element's mounting structure, for measurement of deflection under a load of wind force. For example, an electrode may be applied to the bottom and top of the piezoelectric element. One of the electrodes may be the vehicle aerodynamic element itself if the aerodynamic element is conductive.

The electrode may be separated into electrically isolated segments, either on one of the electrodes or both electrodes. The piezoelectric element may or may not also be separated along the separation between electrodes, depending on the piezoelectric element's qualities.

In some examples, the vehicle control module may pole the piezoelectric material by applying a high voltage across the electrodes. This may or may not be implemented, depending on the piezoelectric material used. For example, some piezoelectric polymers may require a high voltage to successfully pole the polymer. Some piezoelectric plates may not require this poling process.

Electric susceptibility of the piezoelectric material may be measured for each segment by applying a known force and measuring the change in piezoelectric voltage. If the electric susceptibility of the material is consistent and known, this step may be avoided.

When the vehicle aerodynamic element is deflected/bent by the force of wind, it will in turn bend the piezoelectric element attached to it. This creates a change in voltage of the piezoelectric element that can be measured by the change in voltage measured across the top electrode and bottom electrode (or optionally across electrode segments). This voltage is converted into wind force, based on measured piezoelectric strain.

Deflection may be measured using physics calculations for piezoelectric strain, such as dV=(ta*dk*D)/(a*Ea*dx*Aa), where dV is change in piezoelectric voltage used for measuring deflection, ta is thickness of the piezoelectric layer, dk is the change of curvature or deflection of the aerodynamic element, D is a total bending stiffness of aerodynamic element plus piezoelectric layer, a is length of the aerodynamic element, Ea is the elastic modulus of the piezoelectric layer, dx is the piezoelectric strain constant, and Aa is the cross-sectional area of the piezoelectric layer.

Measured force may be aggregated across segments and other piezoelectric elements in the same aerodynamic component to create a two dimensional or three dimensional map of the wind forces sustained by the aerodynamic element. The measured force may be aggregated by using strips of piezoelectric material, creating a web of electrodes and deflection measurements. This can be used to better map forces exerted upon the wing.

When the piezoelectric element is charged with a change in voltage, the piezoelectric element compresses or tenses, in turn bending the connected aerodynamic element. This may be used in a variety of settings, such as a vehicle control module detecting a straight (e.g., on a track), an empty road, that a user is applying acceleration in a straight line, or another situation where the vehicle is not expected to brake or corner. The vehicle control module may apply voltage to piezoelectric elements as necessary to deflect the aerodynamic components. This causes the vehicle to experience less drag, which improves fuel economy and increases vehicle speed.

As another example, the vehicle control module may detect a braking zone, a corner, an upcoming hazard, or another reason to brake or corner, and the vehicle control module applies voltage to piezoelectric elements as necessary to reverse deflection of the aerodynamic components. In this case, the vehicle experiences more downforce, which improves braking and cornering ability.

In various example implementations, a piezoelectric material is applied to the inside or outside of an aerodynamic element in order to: detect and measure deflection, strain, deformation, and damage of an aerodynamic element. In some examples, the system may detect and measure deflection, strain, deformation, and damage of segments of an aerodynamic element using separate electrically isolated electrodes connected to a common piezoelectric element, one separate electrically isolated electrode which is combined with a single larger electrode and separated by a common piezoelectric element or segmented piezoelectric elements, separate electrically isolated electrodes connected to separate electrically isolated piezoelectric elements, etc.

A vehicle control module may be configured to measure force of wind using a change of piezoelectric change of voltage when wind force is applied to a section of an aerodynamic element that does not deform, or by isolating wind force from deflection by applying a piezoelectric assembly to both an inside (e.g., isolated from wind force) and outside (e.g., wind force plus deflection) of a vehicle aerodynamic element.

The vehicle control module may convert a piezoelectric change in voltage into a measurement of aerodynamic element deflection, such as a distance, angle, or force of wind applied. The vehicle control module may perform detection of damaged, bent, or lost aerodynamic components, via detection of an open circuit when monitoring the piezoelectric voltage of an aerodynamic element's assembly.

In some examples, segmenting piezoelectric elements using the above methods may create an array of deflection or force applied to an aerodynamic element. Multiple piezoelectric assemblies may be applied to different parts of an aerodynamic element, optionally in parallel. The resulting measurement of force and/or wind deflection creates a two dimensional or three dimensional (including aerodynamic structure) map of forces applied to the aerodynamic element. This map's resolution may be dependent on the number of piezoelectric materials applied to the aerodynamic element, and the number of segmentations in the electrodes applied to the piezoelectric material. Interpolation may be used to estimate force/deflection between datapoints.

In some examples, a matrix of parallel and perpendicular segments of piezoelectric strips may be created and applied to an aerodynamic element. A strain of each component is measured along each strip, isolating two planes of force applied to the aerodynamic element. Aggregation of all strain measurements creates a three-dimensional map of strain/deflection of the aerodynamic component.

A change in voltage may be applied to a piezoelectric element attached to an aerodynamic element, in order to deflect or apply a force to the aerodynamic element. Bending part (e.g., an electrode segment) or all of the aerodynamic component may allow the vehicle to dynamically alter its aerodynamic components by applying more or less deflection, to increase or reduce downforce. This also allows the vehicle to combat deflection by countering deflection of an aerodynamic element via wind force, by applying a piezoelectric bending force in the opposing direction, or to exaggerate deflection by applying the piezoelectric bending force in the same direction.

In some examples, vehicle control systems may use application of the piezoelectric force to an aerodynamic element for active aerodynamics, such as bending an aerodynamic element in order to reduce drag or apply more downforce dynamically in response to the needs of the vehicle (e.g., oversteer, understeer, lack of downforce, too much drag, etc.), or pre-emptively anticipating braking, accelerating, and steering events and applying active aerodynamic changes using piezoelectric control.

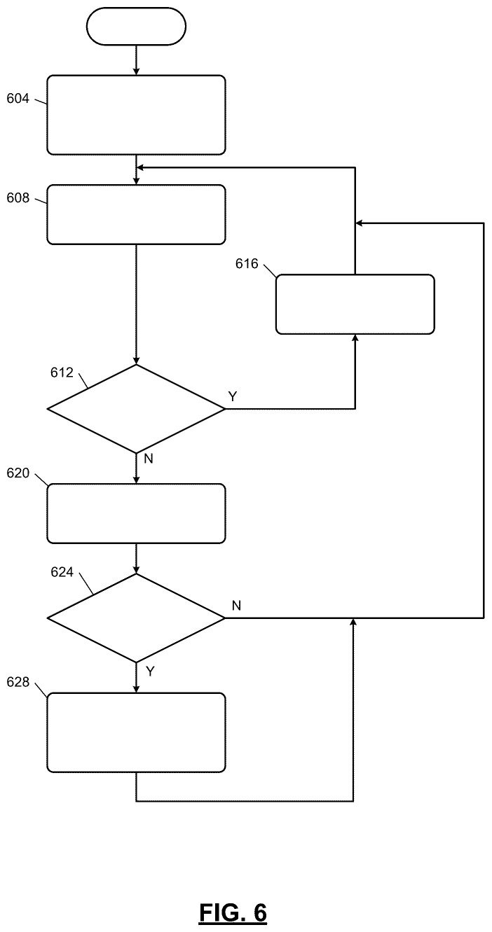

FIG. 6 is a flowchart depicting an example process for applying voltage to a piezoelectric element of a vehicle aerodynamic component. The process may be performed by, for example, the vehicle control module 20 of FIG. 1. At 604, the process begins by obtaining a steady state voltage of a piezoelectric element (e.g., the piezoelectric element 24 of FIG. 1), coupled with an aerodynamic component of a vehicle (such as the aerodynamic element 22 of FIG. 1). For example, the steady state voltage may be a voltage across the piezoelectric element while the vehicle is stationary or the aerodynamic element is not experiencing any wind forces.

At 608, the vehicle control module is configured to obtain a current voltage of the piezoelectric element (e.g., by measuring the voltage using a voltage sensor, etc.). The vehicle control module is configured to determine at 612 whether a speed of the vehicle is equal to zero.

If the speed of the vehicle is zero at 612 (e.g., the vehicle is stationary), control proceeds to 616 to set a steady state voltage value to the current voltage value. For example, if the vehicle is not currently moving, control may use a current voltage reading as a baseline value for the piezoelectric element while it is not experiencing any deformation (such as due to wind forces that may occur when the vehicle is moving).

If the speed of the vehicle is greater than zero at 612, control proceeds to 620 to determine a voltage difference between the steady state voltage of the piezoelectric element and the current voltage value of the piezoelectric element. The voltage difference may be indicative of an amount of force on the piezoelectric element or movement of the piezoelectric element, which may correspond to an amount of deformation of the aerodynamic component of the vehicle.

For example, greater changes in the piezoelectric element voltage may be indicative of greater amounts of deformation in piezoelectric element. A mapping between piezoelectric voltage changes and amounts of deformation of the aerodynamic component may be stored in a memory of the vehicle control module (such as via one or more equations or look up tables), and may be determined during manufacturing, vehicle testing, etc. There may be a linear relationship between piezoelectric element voltage changes and aerodynamic element deformation, a polynomial relationship, an exponential or logarithmic relationship, a non-linear relationship, etc.

At 624, the vehicle control module is configured to determine whether the voltage difference is above a specified threshold. For example, the specified threshold may correspond to an amount of deformation of the vehicle aerodynamic component which will negatively impact the downforce provided by the vehicle aerodynamic component (e.g., beyond a threshold amount of downforce reduction, etc.).

If the voltage difference is above the specified threshold value at 624, control proceeds to 628 to apply a voltage to the piezoelectric element which opposes the voltage difference, in order to reduce deformation of the aerodynamic component and increase downforce. For example, applying a voltage to the piezoelectric element (such as a voltage which is equal and opposite to the current voltage difference), may cause the piezoelectric element to return to a steady state position and push outwards on the surface of the aerodynamic component to increase downforce.

In some examples, the applied voltage may be an amount sufficient to return the voltage across the piezoelectric element to its steady state voltage value. The voltage may be applied selectively, such as to compensate for deformation caused by wind forces (where deformation reduces downforce provided by the aerodynamic component), to add additional downforce as desired (e.g., based on vehicle settings or sensed vehicle parameters), etc.

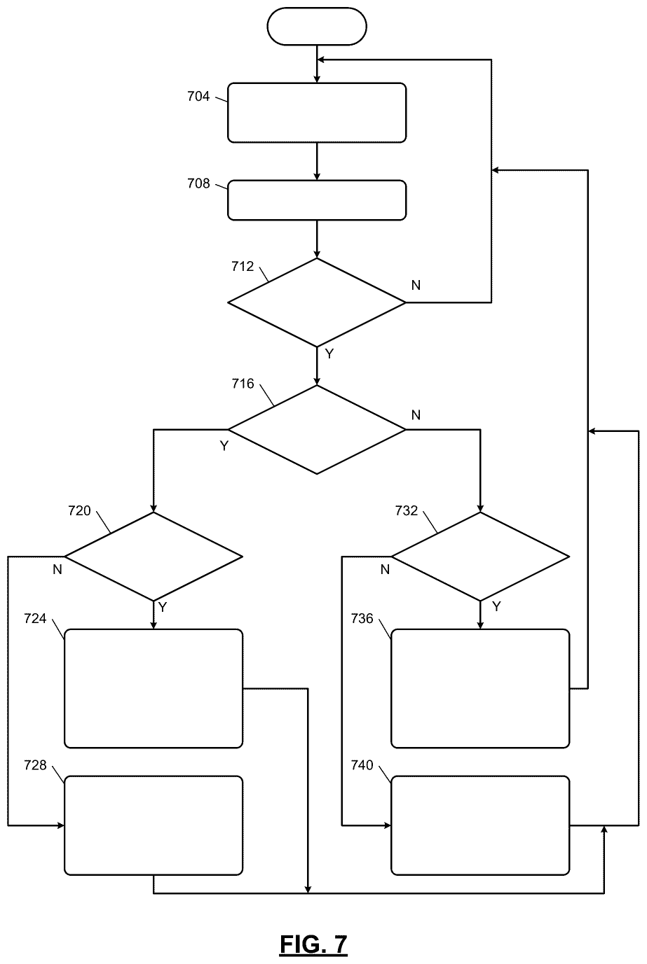

FIG. 7 is a flowchart depicting an example process for selectively applying voltage to front or rear piezoelectric elements to control vehicle downforce. The process may be performed by, for example, the vehicle control module 20 of FIG. 1. At 704, the process begins by obtaining vehicle sensor inputs, such as a steering position, a brake position, a throttle amount, etc. The vehicle sensor inputs may provide information about a current state of motion of the vehicle, and may be obtained via any suitable vehicle sensors (which may be in communication with the vehicle control module).

At 708, the vehicle control module is configured to determine vehicle downforce needs. For example, the vehicle control system may call for a specified amount of downforce based on current motion of the vehicle (e.g., high speed and steering angle), a setting of the vehicle such as a track mode, etc. In some examples, the vehicle downforce needs may be determined based on the obtained vehicle sensor inputs, based on a downforce call or request from a vehicle system control module, etc.

At 712, the vehicle control module is configured to determine whether an aerodynamic adjustment is needed (e.g., by comparing a current amount of downforce to a specified amount of downforce requested by the vehicle control system).

If an aerodynamic adjustment is needed at 712, control proceeds to 716 to determine whether a front aerodynamic component adjustment should be performed. For example, some vehicles may include aerodynamic components at front and rear locations of the vehicle, which may have separate piezoelectric elements attached.

If a front aerodynamic component adjustment is needed at 716, control proceeds to 720 to determine whether more or less downforce is needed. If more downforce is needed, the vehicle control module is configured to apply a voltage to the front piezoelectric element at 724, which opposes a voltage difference between a current voltage of the front piezoelectric element and a steady state voltage of the front piezoelectric element. Applying an opposing voltage to the front piezoelectric element may reduce deflection of a surface of the front aerodynamic component, thereby increasing downforce provided by the front aerodynamic component.

If less downforce is needed from the front aerodynamic component at 720, control proceeds to 728 to apply a larger voltage difference to the front piezoelectric element, such as by increasing a difference between the steady state voltage of the front piezoelectric element and the applied voltage value. This may further increase deflection of the front aerodynamic element, resulting in a reduction of downforce provided by the front aerodynamic element.

If a rear aerodynamic component adjustment is needed at 716, control proceeds to 732 to determine whether more or less downforce is needed. If more downforce is needed, the vehicle control module is configured to apply a voltage to the rear piezoelectric element at 736, which opposes a voltage difference between a current voltage of the rear piezoelectric element and a steady state voltage of the rear piezoelectric element. Applying an opposing voltage to the rear piezoelectric element may reduce deflection of a surface of the rear aerodynamic component, thereby increasing downforce provided by the rear aerodynamic component.

If less downforce is needed from the rear aerodynamic component at 732, control proceeds to 740 to apply a larger voltage difference to the rear piezoelectric element, such as by increasing a difference between the steady state voltage of the rear piezoelectric element and the applied voltage value. This may further increase deflection of the rear aerodynamic element, resulting in a reduction of downforce provided by the rear aerodynamic element.

Some example embodiment herein allow a vehicle control system to measure the deflection of an aerodynamic element in response to external forces. By applying a piezoelectric element along sections of a wing, polymer or plate, the deflection produces a change of voltage in the piezoelectric element. Since piezoelectric materials that are not strained beyond their elastic modulus retain their electrical characteristics, this sensing method can be used consistently. Measuring the deflection of an aerodynamic surface can be important for designing damping, understanding aerodynamics under load, and understanding an aerodynamic element's material characteristics.

The piezoelectric element applied to the aerodynamic element may use top and bottom electrodes to measure the change in voltage when the piezoelectric element receives strain (e.g., deflection) from the attached aerodynamic element. By splitting one of these electrodes into segments that are electrically isolated from each other, the change in voltage due to strain can be measured with greater resolution. This allows for measuring the deflection in specific parts of the aerodynamic element (e.g., the top of a wing). Piezoelectric elements can also be segmented for the same effect.

Similarly, by using multiple piezoelectric elements along an aerodynamic element, the deflection of the aerodynamic component can be measured across different parts of the aerodynamic element. By combining this with the segmented electrodes, this creates a two dimensional map of the deflection encountered by the aerodynamic element.

In some examples, the piezoelectric elements facilitate health monitoring of an aerodynamic element. By having multiple closed circuits on the piezoelectric elements, a detected open circuit indicates that an aerodynamic element is damaged. This may be especially helpful on underfloor components where the user is less likely to notice a damaged aerodynamic element.

The piezoelectric elements may also allow the vehicle control module to exert force on aerodynamic elements using a change in voltage to the piezoelectric element, which may allow a vehicle to bend/deflect its aerodynamic elements in response to external conditions. This can be used by a vehicle control system to control downforce/drag depending on if a vehicle is turning, etc. Using piezoelectric plate strips allows for deformation/deflection of the aerodynamic element in specific areas to affect handling characteristics.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A vehicle control system for a vehicle aerodynamic element, the vehicle control system comprising:
an aerodynamic element coupled with a body of a vehicle, the aerodynamic element configured to deform in response to wind forces exerted on a surface of the aerodynamic element;
at least one piezoelectric element coupled with the aerodynamic element, the piezoelectric element configured to change voltage in response to deformation of the aerodynamic element; and
a vehicle control module configured to:
obtain a steady state voltage value of the piezoelectric element corresponding to a position of the aerodynamic element while a speed of the vehicle is zero;
receive a current voltage value of the piezoelectric element; and
determine a deformation amount of the aerodynamic element based on a voltage difference between the steady state voltage value and the current voltage value.

2. The vehicle control system of claim 1, wherein:
the at least one piezoelectric element includes multiple piezoelectric elements; and
each of the multiple piezoelectric elements is coupled with a different portion of the aerodynamic element.

3. The vehicle control system of claim 2, wherein:
a first one of the multiple piezoelectric elements is coupled with the aerodynamic element in a first orientation;
a second one of the multiple piezoelectric elements is coupled with the aerodynamic element in a second orientation; and
the first orientation is perpendicular to the second orientation.

4. The vehicle control system of claim 1, wherein the at least one piezoelectric element is attached to a top surface of the aerodynamic element.

5. The vehicle control system of claim 1, wherein the at least one piezoelectric element is housed within the aerodynamic element, and is attached to a bottom side of a top surface of the aerodynamic element.

6. The vehicle control system of claim 1, wherein the aerodynamic element is a rear wing of the vehicle.

7. The vehicle control system of claim 1, wherein the at least one piezoelectric element includes a piezoelectric polymer.

8. The vehicle control system of claim 7, wherein:
the piezoelectric polymer includes a single top electrode layer and a matrix layer, the matrix layer including a matrix of bottom electrodes; and
the piezoelectric polymer is positioned between the single top electrode layer and the matrix layer.

9. The vehicle control system of claim 1, wherein the vehicle control module is configured to selectively apply voltage to the piezoelectric element to modify deformation of the aerodynamic element.

10. The vehicle control system of claim 9, wherein the vehicle control module is configured to:
compare the voltage difference to a specified deformation threshold value; and
in response to the voltage difference being greater than or equal to the specified deformation threshold value, apply voltage to the piezoelectric element to reduce deformation of the aerodynamic element to compensate for wind forces on the aerodynamic element.

11. The vehicle control system of claim 9, wherein the vehicle control module is configured to:
determine, based on one or more sensed vehicle parameters, whether an additional downforce condition is satisfied; and
in response to the additional downforce condition being satisfied, apply voltage to the piezoelectric element to reduce deformation of the aerodynamic element.

12. The vehicle control system of claim 11, wherein:
the aerodynamic element is a front aerodynamic element located at a front portion of the vehicle;
the vehicle control system further includes a rear aerodynamic element located at a rear of the vehicle;
the at least one piezoelectric element includes a front piezoelectric element coupled with the front aerodynamic element and a rear piezoelectric element coupled with the rear aerodynamic element;
the vehicle control module is configured to selectively apply voltage to the front piezoelectric element to modify deformation of the front aerodynamic element; and
the vehicle control module is configured to selectively apply voltage to the rear piezoelectric element to modify deformation of the rear aerodynamic element.

13. The vehicle control system of claim 9, wherein the vehicle control module is configured to selectively apply a voltage opposite which is opposite to the voltage difference, to the piezoelectric element, to increase deformation of the aerodynamic element.

14. A method of sensing deformation of a vehicle aerodynamic element, the method comprising:
obtaining a steady state voltage value of at least one piezoelectric element coupled with an aerodynamic element, wherein the aerodynamic element is coupled with a body of a vehicle and configured to deform in response to wind forces exerted on a surface of the aerodynamic element, the piezoelectric element configured to change voltage in response to deformation of the aerodynamic element; and the steady state voltage value corresponds to a position of the aerodynamic element while a speed of the vehicle is zero;
receiving a current voltage value of the piezoelectric element; and
determining a deformation amount of the aerodynamic element based on a voltage difference between the steady state voltage value and the current voltage value.

15. The method of claim 14, further comprising selectively applying voltage to the piezoelectric element to modify deformation of the aerodynamic element.

16. The method of claim 15, further comprising:
comparing the voltage difference to a specified deformation threshold value; and
in response to the voltage difference being greater than or equal to the specified deformation threshold value, applying voltage to the piezoelectric element to reduce deformation of the aerodynamic element to compensate for wind forces on the aerodynamic element.

17. The method of claim 15, further comprising:
determining, based on one or more sensed vehicle parameters, whether an additional downforce condition is satisfied; and
in response to the additional downforce condition being satisfied, applying voltage to the piezoelectric element to reduce deformation of the aerodynamic element.

18. The method of claim 17, wherein the aerodynamic element is a front aerodynamic element located at a front portion of the vehicle, the vehicle includes a rear aerodynamic element located at a rear of the vehicle, and the at least one piezoelectric element includes a front piezoelectric element coupled with the front aerodynamic element and a rear piezoelectric element coupled with the rear aerodynamic element, and the method further includes:
selectively applying voltage to the front piezoelectric element to modify deformation of the front aerodynamic element; and
selectively applying voltage to the rear piezoelectric element to modify deformation of the rear aerodynamic element.

19. The method of claim 15, further comprising selectively applying a voltage opposite which is opposite to the voltage difference, to the piezoelectric element, to increase deformation of the aerodynamic element.

20. The method of claim 14, further comprising adjusting at least one aero surface of the vehicle according to the voltage difference, to increase at least one of a movement efficiency parameter of the vehicle and a downforce parameter of the vehicle.
